(19) United States
(12) Patent Application Publication
(10) Pub. No.: US 2011/0017270 A1
(43) Pub. Date: Jan. 27, 2011

(54) SOLAR TRACKING DEVICE FOR SOLAR CELLS

(76) Inventors: Chien-An Chen, TAIPEI CITY (TW); Zao-Shi Zheng, TAIPEI CITY (TW)

Correspondence Address: NORTH AMERICA INTELLECTUAL PROPERTY CORPORATION, P.O. BOX 506, MERRIFIELD, VA, 22116, US

(21) Appl. No.: 12/842,038

(22) Filed: Jul. 23, 2010

(30) Foreign Application Priority Data
Jul. 24, 2009 (TW) 098125089

(51) Int. Cl. H01L 31/052

(52) U.S. Cl. 136/246

(57) ABSTRACT

A solar tracking device for solar cells includes a supporting unit, a moving unit, a solar receiving unit, and a light sensing unit. The supporting unit has a supporting portion and a rotating portion, and the supporting portion is rotated by the rotating portion. The moving unit is supported by the supporting portion of the supporting unit, and the moving unit is capable of moving along an XY-axis plane. The solar receiving unit is disposed at the moving unit. The light sensing unit is disposed at the moving unit and outputs a light sensing signal. The solar tracking device for solar cells can reduce energy consumption and improve output efficiency of a solar power system during a solar tracking period.

### CROSS-REFERENCE TO RELATED APPLICATIONS

This Non-provisional application claims priority under 35 U.S.C. §119(a) on Patent Application No(s). 098125089 filed in Taiwan, Republic of China on Jul. 24, 2009, the entire contents of which are hereby incorporated by reference.

### BACKGROUND OF THE INVENTION

1. Field of the Invention

This invention relates to a solar tracking device and, more particularly, to a solar tracking device for solar cells.

2. Description of the Related Art

The green energy is the energy with lower environmental pollution or no pollution. The green energy includes wind energy, water energy, tide energy, geothermal energy, and solar energy. Compared with other energy which may be limited by special areas, the solar energy is used at any place of the world shined under the sunlight. Therefore, the solar energy becomes an expected new technique. The key technique for utilizing the solar energy to generate power is photoelectric conversion efficiency by converting the solar energy into the electric energy. The photoelectric converting efficiency is limited by used semiconductor materials or an epitaxial technique, and it is also affected by the design of the whole solar cell module and a system structure cooperating with the solar cell module. Particularly, when light receiving environment changes, the solar cells may be adjusted to maintain the greatest solar energy utilizing efficiency at any time. There are many environmental factors to change the amount of the sunlight to the solar cells and cause the change of the solar energy utilizing efficiency. The general environmental factors may include climate changes, physical features of locating positions of a solar energy system, particles or moisture in air, and a running orbit of the sun.

Solar cells in cooperation with a solar tracking device are a new technique. The solar tracking device used by the solar cells adjusts angles of the solar cells to track the running orbit and position changes of the sun, which helps the solar cells to absorb the greatest amount of the sunlight at the best light incident angle further to improve the light converting efficiency of the whole solar cells. In addition, the power generated by the solar cells is generally fed back to the solar tracking device to be used as driving power of the solar tracking device. However, solar receiving units in the solar cells are heavy, and the solar cells also have the corresponding number of light guiding lenses, such that the load of the solar tracking device is heavy. Therefore, the solar tracking device is not nimble in operation, and the driving power exhausted in the solar tracking period reaches to more than 15 percent of the generated power of the solar cells, which increases about twenty percent of the solar power generation cost.

### BRIEF SUMMARY OF THE INVENTION

One objective of this invention is to provide a solar tracking device for solar cells capable of tracking the sun in a lower power consumption mode.

This invention provides a solar tracking device for solar cells including a supporting unit, a moving unit, a solar receiving unit, and a light sensing unit. The supporting unit has a supporting portion and a rotating portion, and the supporting portion is rotate by the rotating portion. The moving unit is supported by the supporting portion of the supporting unit, and the moving unit is capable of moving along an XY-axis plane. The solar receiving unit is disposed at the moving unit. The light sensing unit is disposed at the moving unit and outputs a light sensing signal.

In addition, the solar tracking device for solar cells may further include a control unit and a driving unit. The control unit is electrically connected with the light sensing unit, and the control unit can receive the light sensing signal to control a moving distance of the moving unit or a rotating angle of the rotating portion. The driving unit is electrically connected with the control unit, the moving unit, and the rotating portion, respectively, and the driving unit is controlled by the control unit to drive the moving unit to move or to drive the rotating portion to rotate. In addition, the moving unit moves along an X axis, and the supporting portion is rotated around the X axis.

According to the above, in the solar tracking device for solar cells in the invention, the moving unit and the rotating portion are used to adjust the position and angle of the solar receiving unit relative to the sun, such that the solar receiving unit can track the sun and maintain the best sunlight incident angle at any time to improve the light utilizing efficiency of the solar receiving unit. Further, in the operation period of the solar tracking device for solar cells, the moving unit just needs to move the solar receiving unit according to the sunlight incident angle instead of moving the whole solar cells including the light guiding lenses, and no power for moving a supporting structure or related components for supporting the solar cells is consumed. Compared with the prior art, the solar tracking device for solar cells in the invention does not need to consume meaningless energy to adjust positions and angles of the components which is irrelevant to receiving the sunlight, such that when the solar cells are used to generate power, the solar cells can consume the lowest energy to generate the greatest power to improve the solar photoelectric converting efficiency and the cost ratio.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a solar tracking device for solar cells according to one preferred embodiment of the invention;

FIG. 2 is another schematic diagram showing a solar tracking device for solar cells according to one preferred embodiment of the invention;

FIG. 3A is a side view showing a solar tracking device for solar cells according to one preferred embodiment of the invention;

FIG. 3B is a side view showing movement of a solar tracking device for solar cells according to one preferred embodiment of the invention;

FIG. 3C is a side view showing movement of a solar tracking device for solar cells according to one preferred embodiment of the invention;

FIG. 4A is a front view showing a solar tracking device for solar cells according to one preferred embodiment of the invention;

FIG. 4B is a front view showing rotation of a solar tracking device for solar cells according to one preferred embodiment of the invention;

FIG. 4C is a front view showing rotation of a solar tracking device for solar cells according to one preferred embodiment of the invention; and

FIG. 5 is a schematic diagram showing a solar tracking device for solar cells in another form according to one preferred embodiment of the invention.

### DETAILED DESCRIPTION OF THE INVENTION

A solar tracking device for solar cells in this invention is designed to track the sun in one day. Since the earth axis and the sun have a special angle, the running orbit of the sun at different places in one day slightly diverges toward the north-south direction according to changes of the time instead of presenting a standard curve formed by rising at the east, moving to the west, and finally falling. As far as the spring and autumn in Taiwan are considered, every day the running orbit of the sun has a diverging angle of seven degrees in the north-south direction of the earth from nine o'clock in the morning to three o'clock in the afternoon. Although relative to the position change of the sun in the east-west direction of the earth, the diverging angle of seven degrees in the north-south direction is small, it sufficiently causes the light utilizing efficiency of the solar cells to be reduced. The solar tracking device for solar cells in one preferred embodiment of the invention is described, and the same element is marked by the same reference number.

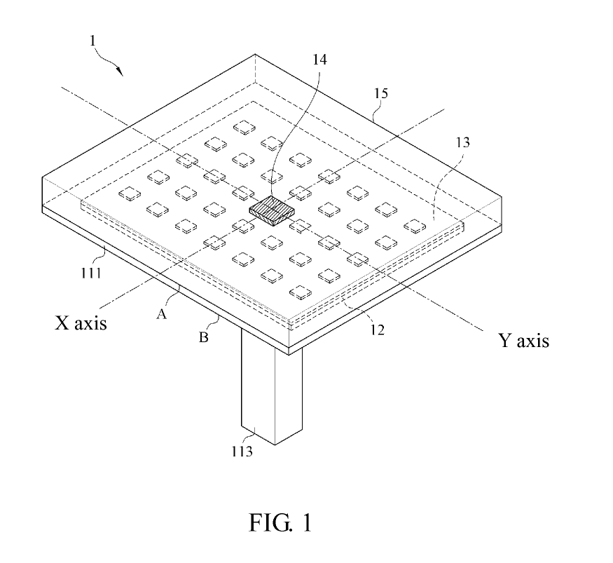

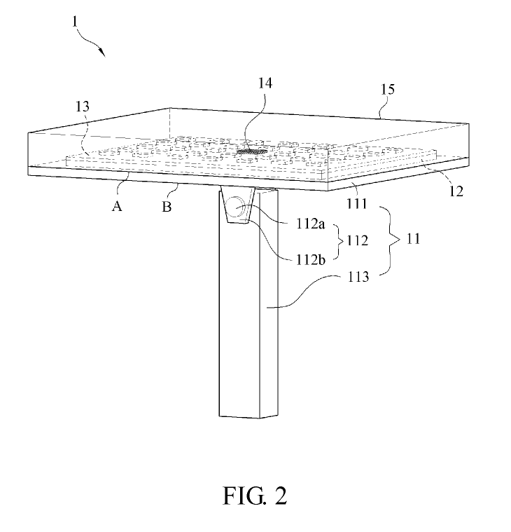

FIG. 1 is a schematic diagram showing a solar tracking device for solar cells according to one preferred embodiment of the invention. FIG. 2 is another schematic diagram showing the solar tracking device for solar cells. In FIG. 1 and FIG. 2, a solar tracking device 1 for solar cells in the preferred embodiment of the invention includes a supporting unit 11, a moving unit 12, a solar receiving unit 13, and a light sensing unit 14. The supporting unit 11 has a supporting portion 111 and a rotating portion 112, and the supporting portion 111 is rotated by the rotating portion 112. The moving unit 12 is supported by the supporting portion 111 of the supporting unit 11, and the moving unit 12 may move along an XY-axis plane. The solar receiving unit 13 is disposed at the moving unit 12. The light sensing unit 14 is also disposed at the moving unit 12 and outputs a light sensing signal.

The supporting unit 11 has the supporting portion 111 and the rotating portion 112. The supporting portion 111 may be any one of a structure or a combination of a plurality of structures adapted for supporting the solar receiving unit 13, and the supporting portion 111 is used for stably exposing the solar receiving unit 13 under the sunlight and assisting the moving unit 12 and the rotating portion 112 in adjusting an angle or a position of the solar receiving unit 13, thereby providing a better platform for the solar receiving unit 13 to perform photoelectric conversion. Although the shape of the supporting portion 111 is not limited, to cooperate with the solar receiving unit 13 having a plane with better efficiency, the supporting portion 111 preferably has a plane or a panel with thickness (as shown in FIG. 1). In addition, the supporting portion 111 has a supporting surface A facing the solar receiving unit 13. In FIG. 1 and FIG. 2, in the embodiment, the supporting surface A is a flat and smooth surface of the supporting portion 111, and the moving unit 12 may move on the supporting portion 111 via the supporting surface A.

The solar receiving unit 13 is a main element in the solar tracking device 1 for solar cells for receiving the sunlight and it is also important for executing the photoelectric conversion. In FIG. 1, in the embodiment, the solar receiving unit 13 is an integral unit including a base and a solar chip further to be disposed on the moving unit 12. In addition, to increase the light utilizing efficiency of the solar receiving unit 13, usually a lens unit 15 is disposed on the solar receiving unit 13 to concentrate environmental light for increasing the light received by the solar receiving unit 13. The lens unit 15 is a lens array including a plurality of lenses, and the lens unit 15 concentrates the incident sunlight to the corresponding solar receiving unit 13. The lens unit 15 may include conventional lenses made of glass or resin or Fresnel lenses. In FIG. 1, in the embodiment, the solar tracking device 1 for solar cells may include a lens unit 15. The lens unit 15 is preferably a concentrated lens unit, and the lens unit 15 corresponds to the solar receiving unit 13 and is disposed on the supporting unit 11. The lens unit 15 may be disposed on the supporting unit 11 by being directly mounted on the supporting portion 111 or covering the supporting portion 111.

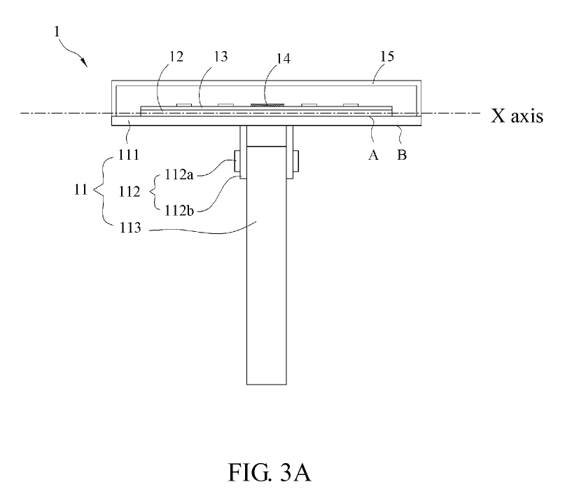

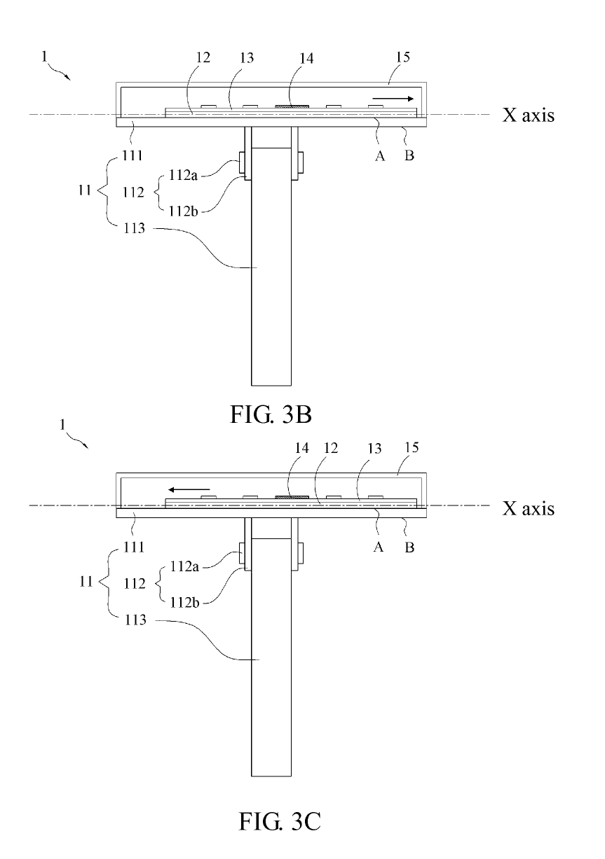

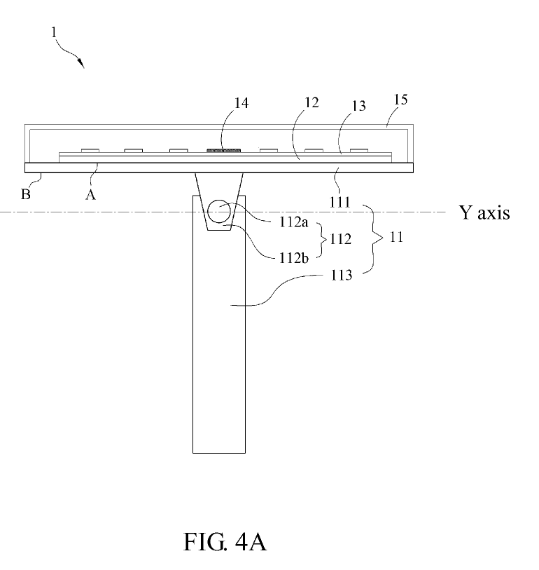

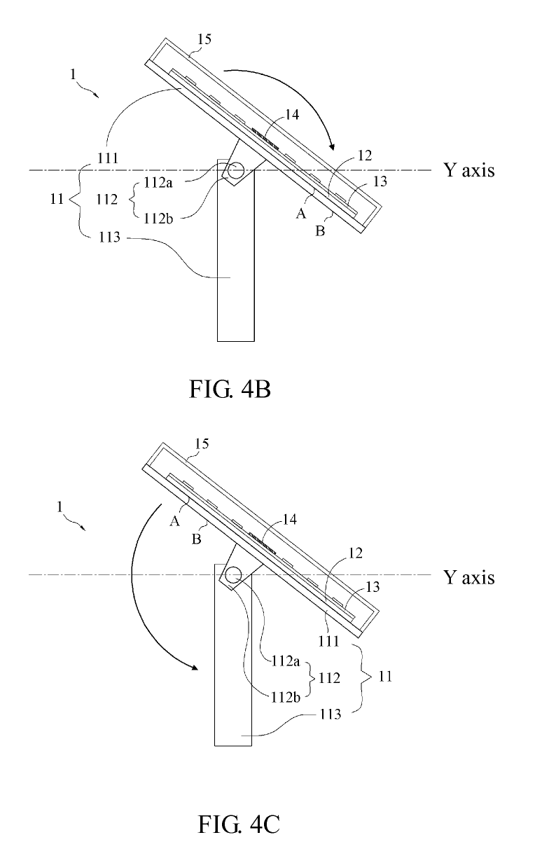

In the embodiment, the moving unit 12 and the rotating portion 112 of the solar tracking device 1 for solar cells are used for allowing the solar receiving unit 13 to track the sun in one day to maintain the best light receiving state. However, the moving unit 12 may move along an XY-axis plane and drive the solar receiving unit 13 disposed on the moving unit 12 to move. FIG. 3A is a side view showing a solar tracking device for solar cells according to one preferred embodiment of the invention. In FIG. 1 and FIG. 3A, the moving unit 12 moves along the XY-axis plane, and the moving unit 12 moves on the supporting portion 111. In addition, in the embodiment, the rotating portion 112 is connected with the supporting portion 111. Further, the rotating portion 112 is connected with a back surface B opposite to the supporting surface A of the supporting portion 111. When the supporting portion 111 is rotated by the rotating portion 112, the rotating portion 112 may drive the solar receiving unit 13 to rotate at the same time. FIG. 4A is a front view showing a solar tracking device for solar cells according to one preferred embodiment of the invention. In FIG. 4A, in the embodiment, the moving unit 12 moves along the X axis, and the rotating portion 112 drives the supporting portion 111 to rotate around the X axis and along the Y axis. In FIG. 1, if the relation between the running orbit of the sun and the earth position is considered, when the solar tracking device 1 for solar cells in the embodiment of the invention is disposed, the X axis in FIG. 1 is about parallel to the north-south direction of the earth, and the Y axis in FIG. 1 is about parallel to the east-west direction of the earth.

According to the above, the dual-axis design may accurately track the sun and save the power consumption at the same time. Since the diverging angle of the running orbit of sun in the north-south direction of the earth in one day does not have a large change, when the sun moves with time, the sunlight shines to the solar receiving unit 13 and may not diverge from the originally set center too far. Thus, the solar receiving unit 13 just needs to be moved along the X axis (that is, the north-south direction of the earth in the embodiment) a little by the moving unit 12 according to the diverging distance, such that the solar receiving unit 13 may receive the sunlight at the better angle again, and the supporting portion 111, the moving unit 12, and the solar receiving unit 13 do not need to be adjusted.

According to the above, the moving unit 12 may be one or more than one structure suitable for driving the solar receiving unit 13 to move. The size and the shape of the moving unit 12 are not limited. However, considering that the moving unit 12 is suitable for connecting the solar receiving unit 13, the moving unit 12 is preferably a plane or a panel with the same or about the same area with the solar receiving unit 13, and the moving unit 12 is connected with the solar receiving unit 13 via the plane or the panel (as shown in FIG. 1). In the embodiment, since the lens unit 15 is disposed on the supporting portion 111, and the plane of the moving unit 12 connected with the solar receiving unit 13 moves on the supporting unit 11, a length of the plane of the moving unit 12 along the X axis needs to be smaller than that of the supporting unit 11 along the X axis (as shown in FIG. 3A). In the embodiment, the moving unit 12 is slidingly disposed on the supporting surface A of the supporting portion 111. The structure and design of the sliding assembly used for achieving the above objective are not limited. The sliding assembly may be a sliding rail, a sliding groove, a sliding cam, a combination thereof capable of cooperating with each other and disposed at the supporting portion 111 and the moving unit 12, respectively, or it may be a ball and a recess or a protrudent portion and an indentation portion capable of cooperating with each and disposed at the supporting portion 111 and the moving unit 12, respectively.

To track the sun along the east-west direction in one day, the supporting unit 11 has the rotating portion 112 to drive the solar receiving unit 13, the moving unit 12, and the supporting portion 111 to rotate around the X axis. FIG. 4A is a front view showing a solar tracking device for solar cells according to one preferred embodiment of the invention. In FIG. 2 or FIG. 4A, in the embodiment, the rotating portion 112 has at least one rotating shaft 112a and a connecting element 112b. The center of the rotating shaft 112a is about parallel to the X axis, and the connecting element 112b is used for connecting the rotating shaft 112a and the supporting portion 111. In another form of the embodiment, the supporting unit 11 may have two rotating portions 112 located at two sides of the supporting unit 11, and each of the rotating portions 112 may have a respective rotating shaft 112a and a respective connecting element 112b.

The light sensing unit 14 is disposed on the moving unit 12, and the light sensing unit may be disposed at any place of the surface of the moving unit 12 for being connected to the solar receiving unit 13. However, to improve detecting accuracy and to reduce the difference between the detecting result and the actual result of the sunlight reception of the solar receiving unit 13, in FIG. 1, in the embodiment, the light sensing unit 14 is disposed at a central area of the moving unit 12, and the light sensing unit 14 is preferably a four-quadrant light sensor. In addition, the light sensing unit 14 may sense the change of the sunlight incident angle and output a light sensing signal according to the sensing result. The light sensing signal may be received by a control unit (not shown), and then the control unit may control a moving distance of the moving unit 12 or a rotating angle of the rotating portion 112 according to the light sensing signal, to adjust the position and angle of the solar receiving unit 13 to track the sun. In the embodiment, the control unit is electrically connected with the light sensing unit 14, and the electrical connection may include wire connection, wireless remote control and so on. However, the invention is not limited thereto.

In the embodiment, the solar tracking device 1 for solar cells can further include a driving unit (not shown) electrically connected with the control unit, the moving unit 12, and the rotating portion 112, respectively. The electrical connection may include wire connection, wireless remote control, and other present electrical connection. However, the invention is not limited thereto. According to the electrical connection, the driving unit may drive the moving unit 12 to move on the supporting surface A of the supporting portion 111 along the X axis or drive the rotating portion 112 to drive the supporting portion 111 to rotate around the X axis according to instructions or signals outputted from the control unit. The driving unit used by the solar tracking device 1 for solar cells does not need special devices, and it may be any device suitable for providing continuous power, such as a linear motor, a stepper motor, an actuating motor, an ultrasonic motor and so on. Certainly, the driving device may also directly provide power for driving other units.

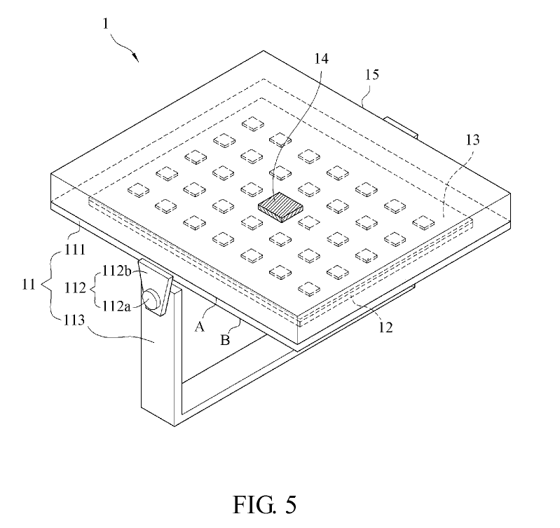

To allow the solar tracking device 1 for solar cells to have a certain space for easily adjusting the position and angle of the solar receiving unit 13 according to the running orbit of the sun in one day, in FIG. 1 and FIG. 2, in the embodiment, the supporting unit 11 may have a holding portion 113. The holding portion 113 is connected with the rotating portion 112 and is used for holding the whole solar tracking device 1 for solar cells and allowing the supporting portion 111 and the structures disposed at the supporting portion 111 to maintain a distance with the ground to be free from touching the ground during rotation. The connection between the supporting portion 111 and the rotating portion 112 is that the supporting portion 111 has a rotating shaft sleeve capable of cooperating with the rotating shaft 112a of the rotating portion 112, and the rotating shaft sleeve is fastened to the rotating shaft 112a of the rotating portion 112. The supporting portion 111 is designed to rotate by the rotating portion 112, the moving unit 12, and the solar receiving unit 13 to rotate together easily, such that during the solar tracking period, the solar tracking device 1 for solar cells may not diverge from original places freely, or the solar tracking device 1 may not be closer to the ground to avoid limiting the rotating angle. Thereby, the supporting portion 111 may be a pole, a column, or a concave-shaped structure. Certainly, the supporting portion 111 may also include other suitable structures capable of achieving the similar functions. In FIG. 2, in the embodiment, the supporting portion 111 is a column. However, in another form of the embodiment, in FIG. 5, the supporting portion 111 is a concave-shaped structure.

The structure of the solar tracking device 1 for solar cells in the embodiment of the invention is described. Then, the solar tracking device 1 for solar cells used in an actual application is taken for example, and the operation of the solar tracking device 1 for solar cells is described.

When the sun rises, an elevating angle between the sun and the ground is small. Therefore, the rotating portion 112 of the solar tracking device 1 for solar cells needs to drive the supporting portion 111, the moving unit 12, and the solar receiving unit 13 to rotate around the X axis (that is, around the north-south direction of the earth). FIG. 4B is a front view showing rotation of a solar tracking device for solar cells according to one preferred embodiment of the invention. The solar receiving unit 13 may be positioned at a place to maintain a greater inclination angle with the ground to allow the sunlight to directly shine the solar receiving unit 13 as far as possible, and the inclination angle may cause the solar receiving unit 13 to be nearly vertical to the ground. However, as the sun gradually moves towards the west, the rotating portion 112 may drive the supporting portion 111, the moving unit 12, and the solar receiving unit 13 to continuously rotate around the X axis towards the opposite direction (as shown in FIG. 4C), such that the supporting portion 111, the moving unit 12, and the solar receiving unit 13 may form a curved moving path around the rotating portion 112, respectively. Finally, when the sun nearly falls, the rotating portion 112 may allow the supporting portion 111, the moving unit 12, and the solar receiving unit 13 to face the west and to utilize the last sunlight before the sun falls in a substantial vertical mode to finish the sunlight absorption in one day.

However, the position of the sun in one day does not only change in the east-west direction, while the position of the sun also gradually diverges toward the north-south direction between the sunrise and the midday. Therefore, when the rotating portion 112 rotates around the X axis according to the running orbit of the sun to change the inclination angle between the solar receiving unit 13 and the ground, the moving unit 12 may move along the X axis according to the diverging angle of the sun towards the north-south direction further to drive the solar receiving unit 13 to be adjusted to a position capable of receiving more sunlight. FIG. 3B is a side view showing movement of a solar tracking device for solar cells according to one preferred embodiment of the invention. Between the midday and the sunset, the position of the sun gradually returns to the original curved orbit. Therefore, the moving unit 12 needs to move along the X axis again to synchronously adjust the solar receiving unit 13. FIG. 3C is a side view showing movement of a solar tracking device for solar cells according to one preferred embodiment of the invention. The incident angle of the sunlight on the solar receiving unit 13 may be maintained at the best state to obtain the largest sunlight.

To sum up, in the solar tracking device for solar cells in the invention, the moving unit and the rotating portion may synchronously adjust the position and inclination angle of the solar receiving unit according to the running orbit of the sun in one day along the east-west direction and the north-south direction of the earth, respectively, to allow the solar receiving unit to accurately track the sun and to maintain the best sunlight incident angle thus to improve the light utilizing efficiency of the solar receiving unit. In the process of operating the solar tracking device for solar cells, the moving unit just needs to move the solar receiving unit a short distance to handle the changes of the sun in one day along the north-south direction of the earth, and the whole solar cells with the light-guiding lens and other additional components do not need to be moved. Further, no energy is consumed for moving the supporting structure for supporting the solar cells. Thereby, when the solar tracking device for solar cells is applied to solar power generation, the greatest power may be outputted while the lowest energy is consumed, thus to improve the photoelectric conversion efficiency and the cost ratio.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A solar tracking device for solar cells comprising:
a supporting unit having a supporting portion and a rotating portion, the supporting portion is rotated by the rotating portion;
a moving unit supported by the supporting portion of the supporting unit, the moving unit being capable of moving along an XY-axis plane;
a solar receiving unit disposed at the moving unit; and
a light sensing unit disposed at the moving unit and outputting a light sensing signal.

2. The solar tracking device for solar cells according to claim 1, wherein the supporting unit further has a holding portion connected with the rotating portion.

3. The solar tracking device for solar cells according to claim 2, wherein the holding portion is a pole, a column, or a concave-shaped structure.

4. The solar tracking device for solar cells according to claim 1, wherein the moving unit is supported by the supporting portion of the supporting unit in a sliding mode.

5. The solar tracking device for solar cells according to claim 1, wherein the moving unit moves along an X axis, and the supporting portion is rotated around the X axis.

6. The solar tracking device for solar cells according to claim 1, wherein the light sensing unit is a four-quadrant light sensor.

7. The solar tracking device for solar cells according to claim 1, further comprising:
a control unit electrically connected with the light sensing unit, the control unit receiving the light sensing signal to control a moving distance of the moving unit or a rotating angle of the rotating portion.

8. The solar tracking device for solar cells according to claim 7, further comprising:
a driving unit electrically connected with the control unit, the moving unit, and the rotating portion, respectively, the driving unit being controlled by the control unit to drive the moving unit to move or to drive the rotating portion to rotate.

9. The solar tracking device for solar cells according to claim 1, further comprising:
a lens unit corresponding to the solar receiving unit and disposed on the supporting portion.

10. The solar tracking device for solar cells according to claim 9, wherein the lens unit comprises a lens array.

11. The solar tracking device for solar cells according to claim 9, wherein the lens unit comprises a plurality of Fresnel lenses.
